(19) United States
(12) Patent Application Publication
(10) Pub. No.: US 2008/0168945 A1
(43) Pub. Date: Jul. 17, 2008

(54) PLASMA GENERATING APPARATUS

(76) Inventor: Hong-Seub Kim, Yongin-si (KR)

Correspondence Address: IPLA P.A., 3580 WILSHIRE BLVD., 17TH FLOOR, LOS ANGELES, CA, 90010, US

(21) Appl. No.: 11/697,678

(22) Filed: Apr. 6, 2007

(30) Foreign Application Priority Data
Jan. 15, 2007 (KR) 10-2007-0004100
Mar. 22, 2007 (KR) 10-2007-0027984

(51) Int. Cl. H05H 1/00; C23C 16/00; H01L 21/306

(52) U.S. Cl. 118/723 I; 156/345.48; 156/345.49; 422/186.04

(57) ABSTRACT

Provided is a plasma generating apparatus. The plasma generating apparatus includes a vacuum chamber, an ElectroStatic Chuck (ESC), an antenna unit, and an antenna cover. The vacuum chamber has a hollow interior and is sealed at a top. The ESC disposed at an internal center of the vacuum chamber receives an external bias Radio Frequency (RF). The antenna unit covers and seals the through-hole of an insulating vacuum plate. The antenna cover covers a top of the antenna unit and has a gas injection port.

### CROSS REFERENCE

This application claims foreign priority under Paris Convention and 35 U.S.C. § 119 to each of Korean Patent Application No. 10-2007-0004100, filed Jan. 15, 2007, and No. 10-2007-0027984, filed Mar. 22, 2007 with the Korean Intellectual Property Office.

### BACKGROUND OF THE INVENTION

1. Field of the Invention

The present invention relates to a plasma generating apparatus. More particularly, the present invention relates to a plasma generating apparatus in which an antenna unit has a composite structure with a plate shape antenna and a coil shape antenna and an ElectroStatic Chuck (ESC) elevates and descends to control a capacitance with the antenna unit, thereby selectively forming an electric field and a magnetic field within a chamber as well as to control even an RF power transmission rate, thereby providing a large-scale high-density plasma with uniform density under both conditions where a gap is provided narrow and wide between the ESC and the antenna unit and also under both conditions where a pressure is provided low and high within the vacuum chamber. The present invention is applicable to a process for semiconductor, Liquid Crystal Display (LCD), Organic Light Emitting Diode (OLED), and solar cell and is also applicable to substance processing based on plasma such as etching, Chemical Vapor Deposition (CVD), plasma doping, and plasma cleaning.

2. Description of the Related Art

In general, plasma, an ionized gas, is the fourth state of matter, not solid, liquid, and gas. Free electrons, positive ions, neutral atoms, and neutron molecules coexist and incessantly interact in plasma. A control of each component and concentration is of importance. In an engineering aspect, plasma is regarded as gas formed and controlled by an external electric field.

A conventional plasma generating apparatus will be described below.

In a conventional plasma generating apparatus shown in FIG. 1, two plate electrodes, a source electrode 11 and an ElectroStatic Chuck (ESC) (or a susceptor) 12, are spaced up/down a predetermined distance apart from each other within a vacuum chamber 10. A substrate 17 is placed on the ESC 12. In the plasma generating apparatus, plasma 18 is generated using an external Radio Frequency (RF) applied to the source electrode 11 and the ESC 12 and a strong electric field induced between the source electrode 11 and the ESC 12.

Non-described reference numerals 13, 14, 15, and 16 denote a source RF, a bias RF, a source matcher, and a bias matcher, respectively.

A conventional Capacitively Coupled Plasma (CCP) type plasma generating apparatus generates a uniform large-scale plasma using a plate capacitor.

A low density plasma and, particularly, the recent minuteness of a semiconductor process and a Liquid Crystal Display (LCD) process results in a need for a low pressure of 10 mTorr or less. However, the CCP type plasma generating apparatus has a disadvantage in that it has a great difficulty in generating and sustaining plasma at the low pressure of 10 mT or less.

The CCP type plasma generating apparatus has a disadvantage in that productivity deteriorates because the low plasma density results in a reduction of etch rate and deposition rate.

In another conventional plasma generating apparatus shown in FIG. 2, a flow of an electric current is induced by a bias RF 24 applied to a substrate 23, which is disposed on an ElectroStatic Chuck (ESC) (or a susceptor) 22 within a vacuum chamber 21, and a source RF 27 applied to an antenna 26, which is disposed on a ceramic vacuum plate 25 covering a top of the vacuum chamber 21. By doing so, a magnetic field is induced and thus an inductive electric field is induced within the vacuum chamber 21. The inductive electric field accelerates electrons, thereby generating plasma 28.

Non-described reference numerals 24a and 27a denote a bias matcher and a source matcher, respectively.

A conventional Inductively Coupled Plasma (ICP) type plasma generating apparatus has an advantage in that it can generate a high-density plasma compared to the CCP type plasma generating apparatus. In general, the ICP type plasma generating apparatus is used in a semiconductor process requiring a characteristic of low pressure because it generates the high-density plasma even at a low pressure of 10 mT or less at which the CCP type plasma generating apparatus cannot do so.

However, the ICP type plasma generating apparatus has a disadvantage in that it has a difficulty in acquiring a uniform plasma density because a point to which an RF power is applied and a ground point from which an electric current flows out are separated from each other and thus, there is an electric potential between both ends.

In recent years, a semiconductor wafer has a large size of 200 mm to 300 mm. In the future, the semiconductor wafer will have a large diameter of 450 mm. Here, plasma uniformity is of much importance. However, the ICP type plasma generating apparatus has a limitation to a large-sized diameter and has a difficulty in guaranteeing large-scale plasma uniformity though the large-scale plasma uniformity should be guaranteed for an LCD device greater than for a semiconductor.

In order to overcome such drawbacks, a long distance is kept between the ESC and the ceramic vacuum plate in the ICP type plasma generating apparatus. This leads to getting longer a residence time of a reaction gas injected into the chamber. The long residence time of the injected reaction gas leads to an increase of a gas ionization rate and a generation of more complex radical than in the CCP type plasma generating apparatus, thereby getting inappropriate to recent semiconductor and LCD processes requiring a delicate radical control.

The ICP type plasma generating apparatus can generate more uniform density plasma at a low pressure where good plasma diffusion is implemented than in the CCP type plasma generating apparatus. However, the ICP type plasma generating apparatus has a drawback that it cannot generate uniform density plasma at a high pressure of 100 mT to 10 T where poor plasma diffusion is implemented.

### SUMMARY OF THE INVENTION

An aspect of exemplary embodiments of the present invention is to address at least the problems and/or disadvantages and to provide at least the advantages described below. Accordingly, an aspect of exemplary embodiments of the present invention is to provide a plasma generating apparatus in which in which an antenna unit has a composite structure with a plate shape antenna and a coil shape antenna and an ElectroStatic Chuck (ESC) elevates and descends to control a capacitance with the antenna unit, thereby selectively forming an electric field and a magnetic field within a chamber as well as to control even an RF power transmission rate, thereby providing a large-scale high-density plasma with uniform density under both conditions where a gap is provided narrow and wide between the ESC and the antenna unit and also under both conditions where a pressure is provided low and high within the vacuum chamber, and it is applicable to a process for semiconductor, Liquid Crystal Display (LCD), Organic Light Emitting Diode (OLED), and solar cell and is also applicable to substance processing based on plasma such as etching, Chemical Vapor Deposition (CVD), plasma doping, and plasma cleaning.

According to one aspect of exemplary embodiments of the present invention, there is provided a plasma generating apparatus. The plasma generating apparatus includes a vacuum chamber, an ESC, an antenna unit, and an antenna cover. The vacuum chamber has a hollow interior and is sealed at a top by an insulating vacuum plate having a through-hole at a center. The ESC is disposed at an internal center of the vacuum chamber, receives an external bias Radio Frequency (RF), and places a substrate thereon. The antenna unit covers and seals the through-hole of the insulating vacuum plate and receives an external source RF. The antenna cover covers a top of the antenna unit and has a gas injection port on a circumferential surface.

The ESC may elevate and descend by a predetermined elevating unit, while controlling a capacitance with the antenna unit.

The elevating unit may be a bellows tube extending from a bottom of the ESC to a bottom of the vacuum chamber.

The bias RF may be separately comprised of a bias low frequency RF and a bias high frequency RF.

The antenna unit may have a coupling structure with a plate shape antenna and a coil shape antenna. The plate shape antenna may generate plasma by capacitive coupling of inducing an electric field with the ESC. The coil shape antenna may generate plasma by inductive coupling of applying a magnetic field and inducing an inductive electric field within the vacuum chamber.

The antenna unit may include a plate shape antenna provided at a center of the antenna unit and a coil shape antenna extending from a circumferential surface of the plate shape antenna so that an electric current induced by an RF power applied from a source can directly flow to an antenna cover.

The antenna unit may include the plate shape antenna provided at a center of the antenna unit and connecting at a center to an RF rod receiving an electric current and the coil shape antenna extending from a circumferential surface of the plate shape antenna so that a flow of an electric current induced by an RF power applied from a source can direct to the coil shape antenna via the plate shape antenna.

The plate shape antenna of the antenna unit may be of a disc shape. The coil shape antenna may include a first straightline part, a circular arc part, and a second straightline part. The first straightline part radially extends from the circumferential surface of the plate shape antenna. The circular arc part is curved and extends from an end of the first straightline part, drawing the same concentric arc as that of the plate shape antenna. The second straightline part radially extends from an end of the circular arc part.

The second straightline part of the coil shape antenna may be inserted at a front end into a concave groove part provided at a top of the vacuum chamber, and be coupled and fixed by a predetermined coupler to the vacuum chamber.

The plasma generating apparatus may further include a capacitor at the front end of the second straightline part of the coil shape antenna.

The capacitor may be formed by intervening a dielectric substance between the front end of the second straightline part and the concave groove part of the vacuum chamber.

The antenna unit may have a single structure in which a single coil shape antenna extends from the circumferential surface of the plate shape antenna.

The antenna unit may have a complex structure in which a plurality of coil shape antennas extend from the circumferential surface of the plate shape antenna.

The antenna unit may include a concave part and a plurality of gas jet ports. The concave part is concaved downward so that a center can be on the same line as the through-hole of the insulating vacuum plate of the vacuum chamber. The plurality of gas jet ports are provided at a surface of the concave part.

The antenna unit may further include a gas distribution plate between the concave part and the antenna cover.

The plate shape antenna of the antenna unit may be of a rectangular plate shape. The coil shape antenna may be of a multi-bent straightline shape in which it vertically extends from the circumferential surface of the plate shape antenna, extends from an end of a vertical extension in parallel with the rectangular plate shape, and vertically extends outward from an end of a parallel extension.

A ratio of Capacitively Coupled Plasma (CCP) component to Inductively Coupled Plasma (ICP) component may be controllable by varying an impedance (Z_{ch}) of the vacuum chamber and an impedance (Z_{coil}) of the coil shape antenna.

The impedance (Z_{ch}) may be expressed by Equation:

Z_{ch}=1/ωC_{ch}

where,
Z_{ch}: impedance of vacuum chamber,
C_{ch}: capacitance of vacuum chamber, and
ω: frequency.

A capacitance (C_{ch}) of the vacuum chamber may be expressed by Equation:

C_{ch}=∈(A/d_{gap})

where,
∈: dielectric constant within vacuum chamber,
A: area of plate shape antenna, and
d_{gap}: distance of gap between plate shape antenna and ESC.

The capacitance (C_{ch}) of the vacuum chamber may increase by decreasing the distance (d_{gap}), and a CCP component ratio may increase by decreasing the impedance (Z_{ch}).

The impedance (Z_{coil}) of the coil shape antenna may be expressed by Equation:

Z_{coil}=R+j ωL+1/jωC

where,
j: imaginary unit (j²=−1),
ω: frequency,
L: inductance, and
C: capacitance.

The capacitance (C) may be expressed by Equation:

C=∈(S/d)

where,
∈: dielectric constant of dielectric substance,
S: area of dielectric substance, and
d: thickness of dielectric substance.

The vacuum chamber may include upper and lower wall bodies and a gap block. The upper and lower wall bodies may form a frame of the vacuum chamber and be separated in a predetermined position and the gap block may be airtightly interposed between the upper and lower wall bodies so that a capacitance is controlled between an ESC and an antenna unit.

The vacuum chamber may have a short vertical length by a narrow gap to have a high capacitance between an ESC and an antenna unit.

The vacuum chamber may have a long vertical length by a wide gap to have a low capacitance between an ESC and an antenna unit.

According to another aspect of exemplary embodiments of the present invention, there is provided a plasma generating apparatus. The plasma generating apparatus includes a vacuum chamber, an ESC, and an antenna unit. The vacuum chamber has a hollow interior, is covered at an opened top with an insulating vacuum plate, and has a gas injection port thereunder. The ESC is disposed at an internal center of the vacuum chamber, receives an external bias RF, and places a substrate thereon. The antenna unit is disposed over the insulating vacuum plate to be spaced a predetermined distance apart from the insulating vacuum plate and receives an external source RF.

The ESC may elevate and descend by a predetermined elevating unit, while controlling a capacitance with the antenna unit.

The elevating unit may be a bellows tube extending from a bottom of the ESC to a bottom of the vacuum chamber.

The bias RF may be separately comprised of a bias low frequency RF and a bias high frequency RF.

The antenna unit may have a coupling structure with a plate shape antenna and a coil shape antenna. The plate shape antenna may generate plasma by capacitive coupling of inducing an electric field with the ESC. The coil shape antenna may generate plasma by inductive coupling of applying a magnetic field and inducing an inductive electric field within the vacuum chamber.

The plasma generating apparatus may further include a gas distribution plate provided at a bottom of the insulating vacuum plate and enabling a uniform downward distribution of a gas injected through the gas injection port.

### BRIEF DESCRIPTION OF THE DRAWINGS

The accompanying drawings, which are included to aid in The above and other objects, features and advantages of the present invention will become more apparent from the following detailed description when taken in conjunction with the accompanying drawings in which:

FIG. 1 is a schematic view illustrating an example of a conventional plasma generating apparatus;

FIG. 2A is a schematic view illustrating another example of a conventional plasma generating apparatus;

FIG. 2B is a schematic plan view illustrating an ICP antenna of FIG. 2A;

FIG. 3 is a schematic cross-sectional view illustrating a plasma generating apparatus according to an exemplary embodiment of the present invention;

FIG. 4 is a plan view of FIG. 3;

FIG. 5 is a cross-sectional view taken along line A-A′ of FIG. 4;

FIG. 6 is a schematic circuit diagram illustrating an equivalent circuit of a plasma generating apparatus according to an exemplary embodiment of the present invention;

FIG. 7 is a schematic plan view illustrating a plasma generating apparatus according to another exemplary embodiment of the present invention;

FIGS. 8A to 8D are schematic plan views illustrating antenna units in a plasma generating apparatus according to another exemplary embodiment of the present invention;

FIG. 9 is a schematic plan view illustrating an antenna unit of a plasma generating apparatus according to a further another exemplary embodiment of the present invention;

FIG. 10 is a schematic cross-sectional view illustrating a plasma generating apparatus according to a further another exemplary embodiment of the present invention;

FIG. 11 is a schematic cross-sectional view illustrating a plasma generating apparatus according to a yet another exemplary embodiment of the present invention;

FIG. 12 is a schematic cross-sectional view illustrating a plasma generating apparatus according to a still another exemplary embodiment of the present invention;

FIG. 13 is a schematic cross-sectional view illustrating a plasma generating apparatus according to a still another exemplary embodiment of the present invention; and

FIG. 14 is a schematic plan view illustrating an antenna unit of FIG. 13.

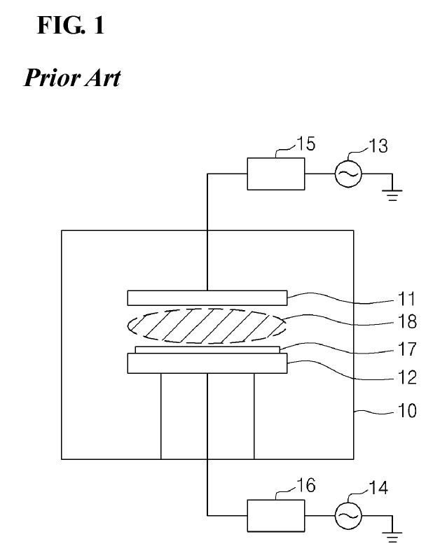

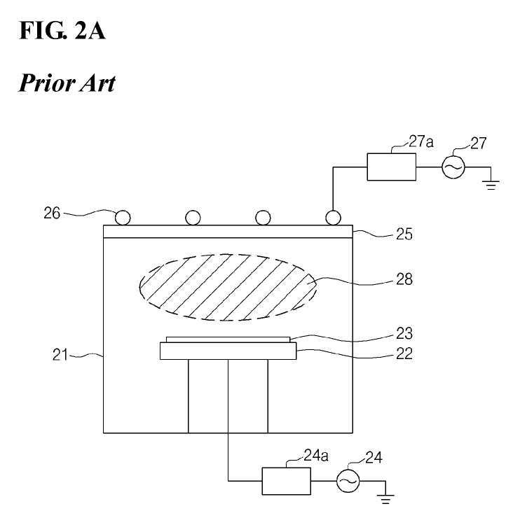

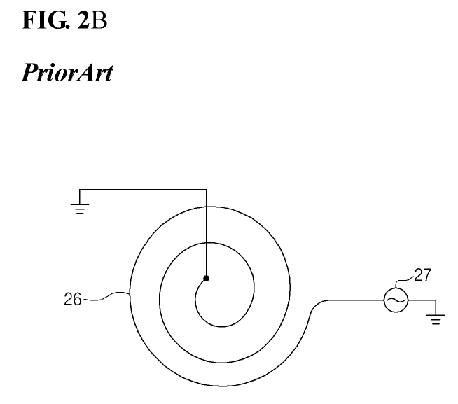

Throughout the drawings, the same drawing reference numerals will be understood to refer to the same elements, features and structures.

### DETAILED DESCRIPTION OF THE INVENTION

Exemplary embodiments of the present invention will now be described in detail with reference to the annexed drawings. In the following description, a detailed description of known functions and configurations incorporated herein has been omitted for conciseness.

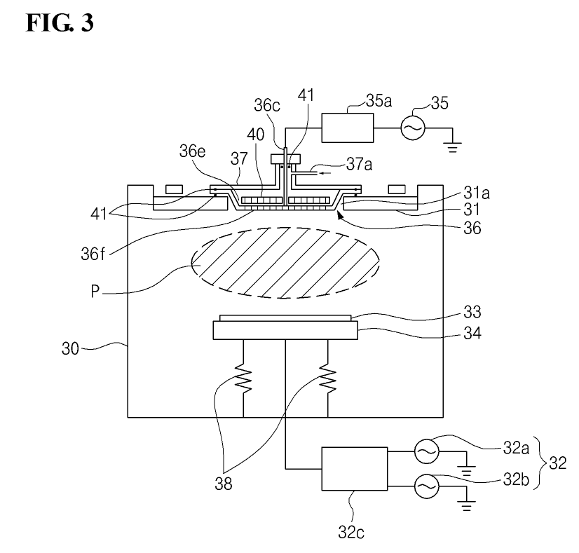

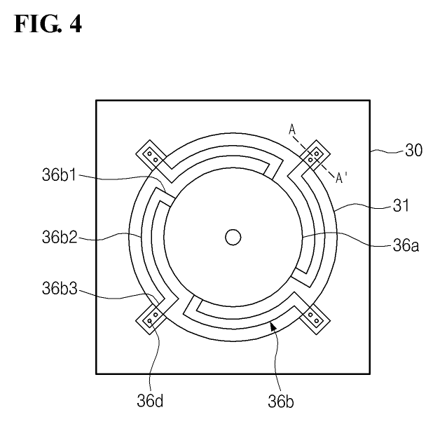

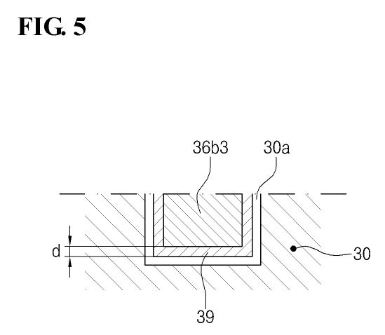

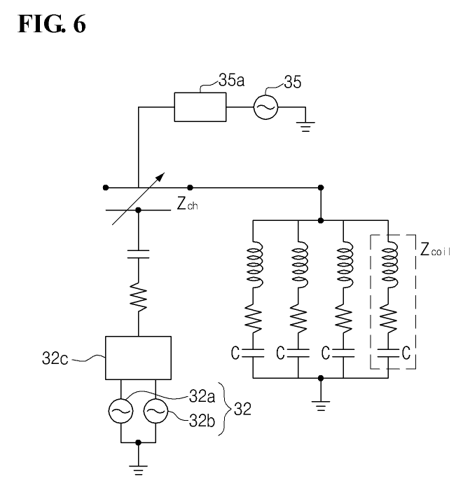

FIG. 3 is a schematic cross-sectional view illustrating a plasma generating apparatus according to an exemplary embodiment of the present invention. FIG. 4 is a plan view of FIG. 3. FIG. 5 is a cross-sectional view taken along line A-A′ of FIG. 4. FIG. 6 is a schematic circuit diagram illustrating an equivalent circuit of the plasma generating apparatus according to an exemplary embodiment of the present invention.

As shown in FIGS. 3 to 6, the plasma generating apparatus includes a vacuum chamber 30 whose interior is hollow and whose top is sealed by an insulating vacuum plate 31; an ElectroStatic Chuck (ESC) 34 disposed at an internal center of the vacuum chamber 30 and placing a substrate 33 thereon; an antenna unit 36 covering and sealing a through-hole 31a of the insulating vacuum plate 31; and an antenna cover 37 covering a top of the antenna unit 36.

The vacuum chamber 30 is of a rectangular box shape whose interior is hollow and whose top is opened. The opened top of the vacuum chamber 30 is sealed by the insulating vacuum plate 31 having the through-hole 31a at a center. A concave groove part 30a is concavely indented to insert a front end of a second straightline part 36b3 of a coil shape antenna 36b and is provided at a top of the vacuum chamber 30 corresponding to an outer wall of the insulating vacuum plate 31.

The ESC (or a susceptor) 34 is of a plate shape in which it is disposed at the internal center of the vacuum chamber 30, receives an external bias RF 32, and places the substrate 33 thereon. A bellows tube 38 is provided at a bottom of the ESC 34 so that it can elevate and descend, controlling a gap with the antenna unit 36.

The bias RF 32 is comprised of a bias low frequency RF 32a and a bias high frequency RF 32b for separate application.

The antenna unit 36 covers and seals the through-hole 31a of the insulating vacuum plate 31 and receives an external source RF 35. In particular, the antenna unit 36 has a coupling structure with a plate shape antenna 36a and a coil shape antenna 36b. The plate shape antenna 36a generates plasma (P) by capacitive coupling of inducing an electric field with the ESC 34. The coil shape antenna 36b generates plasma (P) by inductive coupling of applying a magnetic field and inducing an inductive electric field within the vacuum chamber 30.

The antenna unit 36 includes the plate shape antenna 36a provided at a center of the antenna unit 36 and connecting at a center to an RF rod 36c receiving an electric current and the coil shape antenna 36b extending from a circumferential surface of the plate shape antenna 36a so that a flow of an electric current induced by an RF power applied from a source can direct to the coil shape antenna 36b via the plate shape antenna 36a.

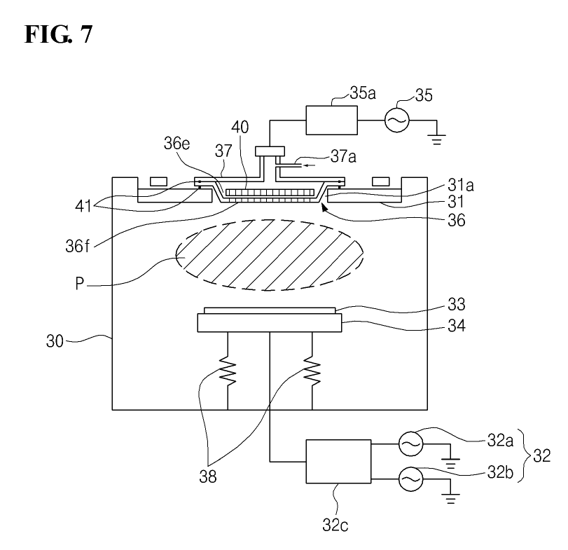

FIG. 7 is a schematic plan view illustrating a plasma generating apparatus according to another exemplary embodiment of the present invention.

As shown in FIG. 7, an antenna unit 36 can include a plate shape antenna 36a provided at a center of the antenna unit 36 and a coil shape antenna 36b extending from a circumferential surface of the plate shape antenna 36a so that an electric current induced by an RF power applied from a source can directly flow to an antenna cover 37, not passing through the RF rod 36c of FIG. 3, to flow to the plate shape antenna 36a and the coil shape antenna 36b.

The plate shape antenna 36a of the antenna unit 36 is of a disc shape. The coil shape antenna 36b includes a first straightline part 36b1 radially extending from the circumferential surface of the plate shape antenna 36a; a circular arc part 36b2 curved and extending from an end of the first straightline part 36b1, drawing the same concentric arc as that of the plate shape antenna 36a; and a second straightline part 36b3 radially extending from an end of the circular arc part 36b2.

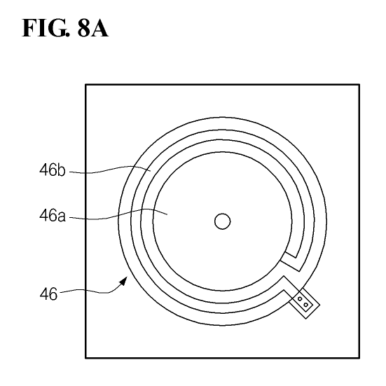

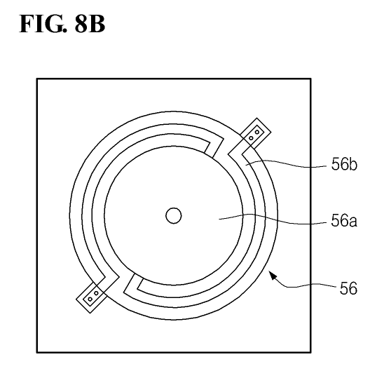

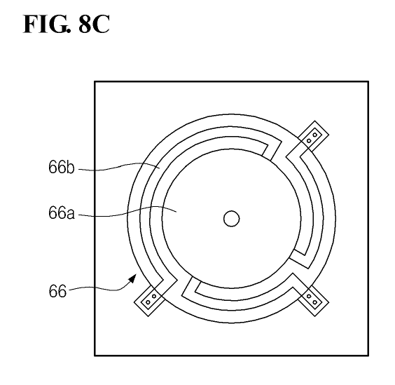

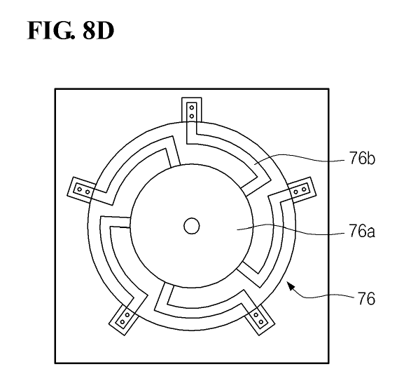

FIGS. 8A to 8D are schematic plan views illustrating antenna units in a plasma generating apparatus according to another exemplary embodiment of the present invention.

As shown in FIG. 8A, an antenna unit 46 has a single structure in which a single coil shape antenna 46b extends from a circumferential surface of a plate shape antenna 46a.

As shown in FIGS. 8B to 8D, an antenna unit 56, 66, or 76 can be provided so that a plurality of coil shape antennas 56b, 66b, or 76b can extend from a circumferential surface of a plate shape antenna 56a, 66a, or 76a like an n-point branch structure.

The second straightline part 36b3 of the coil shape antenna 36b is inserted at a front end into the concave groove part 30a provided at the top of the vacuum chamber 30, and is coupled and fixed by a predetermined coupler 36d to the vacuum chamber 30.

A capacitor is further provided at the front end of the second straightline part 36b3 of the coil shape antenna 36b. In the present invention, the capacitor is formed by intervening a dielectric substance 39 between the front end of the second straightline part 36b3 and the concave groove part 30a of the vacuum chamber 30.

The antenna unit 36 includes a concave part 36e concaved downward so that its center can be on the same line as the through-hole 31a of the insulating vacuum plate 31; and a plurality of gas jet ports 36f provided at a surface of the concave part 36e.

The antenna unit 36 further includes a gas distribution plate 40 between the concave part 36e and the antenna cover 37.

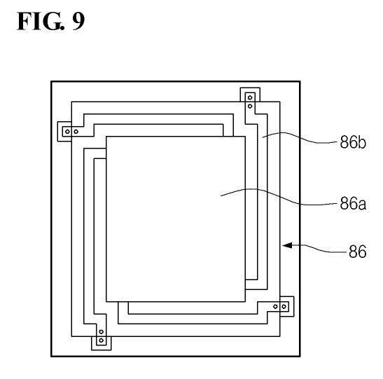

FIG. 9 is a schematic plan view illustrating an antenna unit of a plasma generating apparatus according to a further another exemplary embodiment of the present invention.

As shown in FIG. 9, a plate shape antenna 86a of the antenna unit 86 is of a rectangular plate shape. A coil shape antenna 86b is of a multi-bent straightline shape in which it vertically extends from a circumferential surface of the plate shape antenna 86a, extends from an end of a vertical extension in parallel with the rectangular plate shape, and vertically extends outward from an end of a parallel extension.

Such a rectangular substrate would be applicable to various fields such as Liquid Crystal Display (LCD), Organic Liquid Crystal Display (OLCD), and solar cell.

The antenna cover 37 covers the gas distribution plate 40 and is sealantly coupled to the top of the antenna unit 36. The antenna cover 37 is of a shape in which it exposes the RF rod 36c at a center and has a gas injection port 37a at a predetermined circumference portion.

Non-described reference numeral 41 denotes seals for keeping airtight between the insulating vacuum plate 31 and the antenna unit 36, and between the antenna unit 36 and the antenna cover 37, and between an inner surface of the antenna cover 37 and the RF rod 36c.

In the above-constructed plasma generating apparatus according to the present invention, the substrate 33 is placed on the ESC 34 within the vacuum chamber 30. A gap between the antenna unit 36 and the ESC 34 is controlled using the bellows tube 38. The RF powers 32 and 35 each are applied to the interior of the vacuum chamber 30 via respective matcher 32c and 35a. A gas is injected through the gas injection port 37a to be uniformly distributed via the gas distribution plate 40 and the gas jet port 36f. Thus, plasma (P) is generated within the vacuum chamber 30.

The bias low frequency RF 32a of the bias RF 32 is within a range of about 100 KHz to 4 MHz. The bias high frequency RF 32b is within a range of about 4 MHz to 100 MHz.

Plasma (P) is generated in a CCP mode where an electric field is induced between the plate shape antenna 36a and the ESC 34 and in an ICP mode where a magnetic field is induced between the coil shape antenna 36b and the ESC 34.

In each of the CCP and ICP modes, a component can be adjusted. Referring to an equivalent circuit of FIG. 6, an impedance (Z_{ch}) and a capacitance (C_{ch}) of the vacuum chamber 30 are expressed by Equation:

Z_{ch}=1/ωC_{ch}

C_{ch}=∈(A/d_{gap})

### Where,

Z_{ch}: impedance of vacuum chamber 30,
C_{ch}: capacitance of vacuum chamber 30,

### ω: Frequency,

∈: Dielectric constant within vacuum chamber 30,
A: area of plate shape antenna 36a, and
D_{gap}: gap distance between plate shape antenna 36a and ESC 34.

The impedance (Z_{ch}) can be controlled by controlling the capacitance (C_{ch}). The dielectric constant (∈) approximates to ∈_{∘} at a low pressure. A CCP component ratio can increase or decrease by controlling the gap. When the gap gets small, the impedance (Z_{ch}) decreases. Thus, the CCP component ratio increases.

When the gap gets large, the impedance (Z_{ch}) increases. Thus, the CCP component ratio decreases.

In FIG. 6, an impedance (Z_{coil}) of the coil shape antenna 36b can be expressed by Equation:

Z_{coil}=R+jωL+1/jωC

where,
j: imaginary unit (j²=−1),
ω: frequency,
L: inductance, and
C: capacitance.

The capacitance (C) can be expressed by Equation:

C=∈(S/d)

where,
∈: dielectric constant of dielectric substance,
S: area of dielectric substance, and
d: thickness of dielectric substance.

The capacitance (C) can vary by controlling the thickness (d) of the dielectric substance 39.

As such, the capacitor is formed by intervening the dielectric substance 39 between the coil shape antenna 36b and the vacuum chamber 30.

The dielectric substance 39 can use Teflon, Vespel, Peek, and Ceramic.

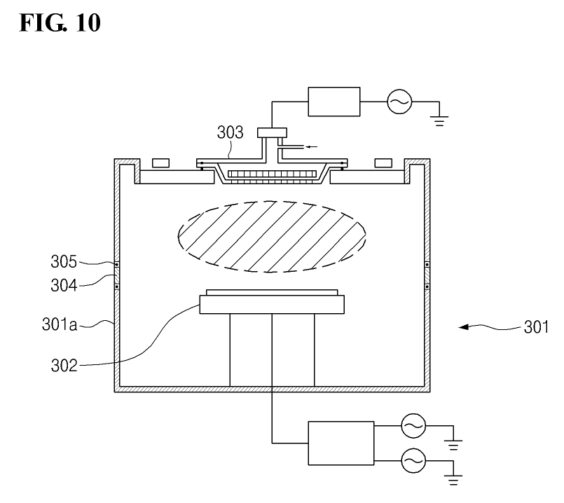

FIG. 10 is a schematic cross-sectional view illustrating a plasma generating apparatus according to a further another exemplary embodiment of the present invention.

As shown in FIG. 10, a vacuum chamber 301 can include upper and lower wall bodies 301a forming a frame of the vacuum chamber 301 and a gap block 304 airtightly interposed between the upper and lower wall bodies 301a. The upper and lower wall bodies 301a can be separated in a predetermined position to control a capacitance between an ESC 302 and an antenna unit 303.

The vacuum chamber 301 can be adjusted in height as desired by using a plurality of gap blocks 304. It is desirable that sealing members 305 are provided between the gap block 304 and the upper and lower wall bodies 301a, respectively.

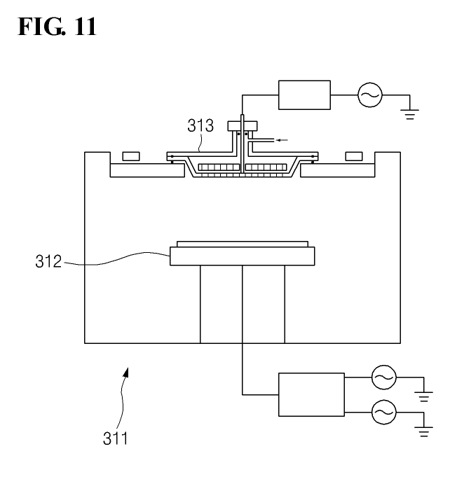

FIG. 11 is a schematic cross-sectional view illustrating a plasma generating apparatus according to a yet another exemplary embodiment of the present invention.

As shown in FIG. 11, a vacuum chamber 311 can be of a structure in which it has a short vertical length by a narrow gap to have a high capacitance between an ESC 312 and an antenna unit 313.

The ESC 312 is of a fixed type in which its own elevation and descent cannot be made within the vacuum chamber 311.

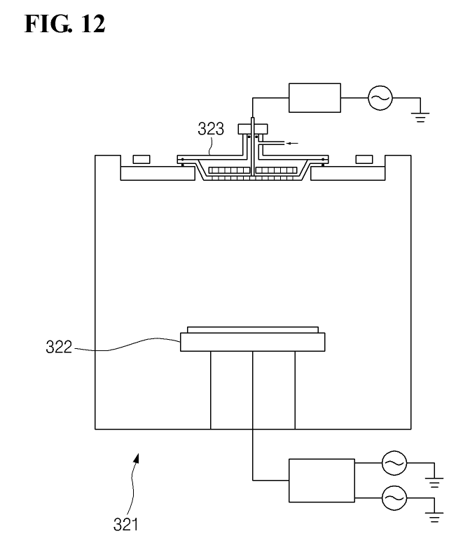

FIG. 12 is a schematic cross-sectional view illustrating a plasma generating apparatus according to a still another exemplary embodiment of the present invention.

A vacuum chamber 321 can be of a structure in which it has a long vertical length by a wide gap to have a low capacitance between an ESC 322 and an antenna unit 323.

The ESC 322 is of a fixed type in which its own elevation and descent cannot be made within the vacuum chamber 321.

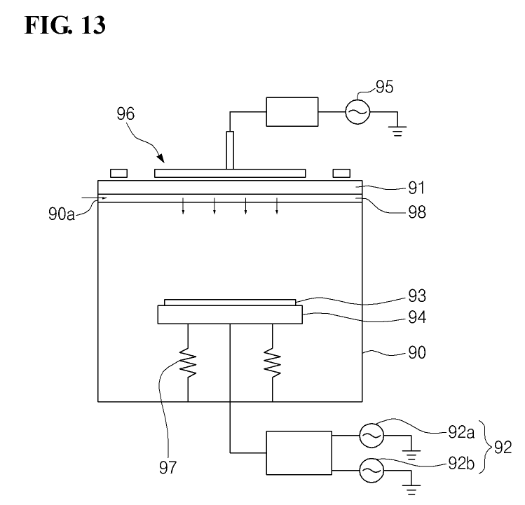

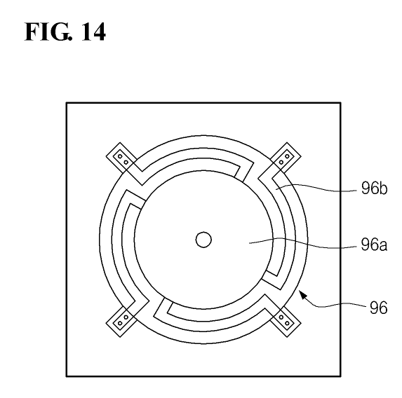

FIG. 13 is a schematic cross-sectional view illustrating a plasma generating apparatus according to a still another exemplary embodiment of the present invention. FIG. 14 is a schematic plan view illustrating an antenna unit of FIG. 13.

As shown in FIGS. 13 and 14, the plasma generating apparatus includes a vacuum chamber 90 having a hollow interior, covered at an opened top with an insulating vacuum plate 91, and having a gas injection port 90a thereunder; an ESC 94 disposed at an internal center of the vacuum chamber 90, receiving an external bias RF 92, and placing a substrate 93 thereon; and an antenna unit 96 disposed over the insulating vacuum plate 91 to be spaced a predetermined distance apart from the insulating vacuum plate 91 and receiving an external source RF 95.

This construction is almost the same as that of the plasma generating apparatus of FIG. 3 except for a structural difference that the antenna unit 96 is installed outside the vacuum chamber 90 and a gas is injected via the gas injection port 90a of the vacuum chamber 90 without passing the antenna unit 96.

A gas distribution plate 98 is further provided under the insulating vacuum plate 91 and enables a uniform downward distribution of a gas injected via the gas injection port 90a.

In addition, an elevating unit is provided as a bellows tube 97 extending from a bottom of the ESC 94 to a bottom of the vacuum chamber 90.

The bias RF 92 is comprised of a bias low frequency RF 92a and a bias high frequency RF 92b for separate application.

The antenna 96 has a coupling structure with a plate shape antenna 96a and a coil shape antenna 96b. The plate shape antenna 96a generates plasma (P) by capacitive coupling of inducing an electric field with the ESC 94. The coil shape antenna 96b generates plasma (P) by inductive coupling of applying a magnetic field and inducing an inductive electric field within the vacuum chamber 90.

As described above, in the inventive plasma generating apparatus, the antenna unit has a composite structure with the plate shape antenna and the coil shape antenna, and the ESC elevates and descends to control the capacitance with the antenna unit so that an electric field and a magnetic field can be selectively formed within the vacuum chamber as well as to control even an RF power transmission rate. Thus, the plasma generating apparatus provides an effect of acquiring a uniform plasma density at the time of forming a large-scale high-density plasma or under both conditions where narrow and wide gaps are provided between the ESC and the antenna unit and even under both conditions where low and high pressures are provided within the vacuum chamber. The inventive plasma generating apparatus is applicable to a process for semiconductor, Liquid Crystal Display (LCD), Organic Light Emitting Diode (OLED), and solar cell and is also applicable to substance processing based on plasma such as etching, Chemical Vapor Deposition (CVD), plasma doping, and plasma cleaning.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A plasma generating apparatus comprising:
a vacuum chamber whose interior is hollow and whose top is sealed by an insulating vacuum plate having a through-hole at a center;
an ElectroStatic Chuck (ESC) disposed at an internal center of the vacuum chamber, receiving an external bias Radio Frequency (RF), and placing a substrate thereon;
an antenna unit covering and sealing the through-hole of the insulating vacuum plate and receiving an external source RF; and
an antenna cover covering a top of the antenna unit and having a gas injection port on a circumferential surface.

2. The apparatus of claim 1, wherein the ESC elevates and descends by a predetermined elevating unit, while controlling a capacitance with the antenna unit.

3. The apparatus of claim 2, wherein the elevating unit is a bellows tube extending from a bottom of the ESC to a bottom of the vacuum chamber.

4. The apparatus of claim 1, wherein the bias RF is separately comprised of a bias low frequency RF and a bias high frequency RF.

5. The apparatus of claim 1, wherein the antenna unit has a coupling structure with a plate shape antenna and a coil shape antenna, and
wherein the plate shape antenna generates plasma by capacitive coupling of inducing an electric field with the ESC, and the coil shape antenna generates plasma by inductive coupling of applying a magnetic field and inducing an inductive electric field within the vacuum chamber.

6. The apparatus of claim 5, wherein the antenna unit comprises the plate shape antenna provided at a center of the antenna unit and connecting at a center to an RF rod receiving an electric current and the coil shape antenna extending from a circumferential surface of the plate shape antenna so that a flow of an electric current induced by an RF power applied from a source can direct to the coil shape antenna via the plate shape antenna.

7. The apparatus of claim 5, wherein the antenna unit comprises:
a plate shape antenna provided at a center of the antenna unit; and
a coil shape antenna extending from a circumferential surface of the plate shape antenna,
whereby an electric current induced by an RF power applied from a source directly flows to an antenna cover.

8. The apparatus of claim 6, wherein the plate shape antenna of the antenna unit is of a disc shape, and
wherein the coil shape antenna comprises:
a first straightline part radially extending from the circumferential surface of the plate shape antenna;
a circular arc part curved and extending from an end of the first straightline part, drawing the same concentric arc as that of the plate shape antenna; and
a second straightline part radially extending from an end of the circular arc part.

9. The apparatus of claim 7, wherein the plate shape antenna of the antenna unit is of a disc shape, and
wherein the coil shape antenna comprises:
a first straightline part radially extending from the circumferential surface of the plate shape antenna;
a circular arc part curved and extending from an end of the first straightline part, drawing the same concentric arc as that of the plate shape antenna; and
a second straightline part radially extending from an end of the circular arc part.

10. The apparatus of claim 8, wherein the second straightline part of the coil shape antenna is inserted at a front end into a concave groove part provided at a top of the vacuum chamber, and is coupled and fixed by a predetermined coupler to the vacuum chamber.

11. The apparatus of claim 9, wherein the second straightline part of the coil shape antenna is inserted at a front end into a concave groove part provided at a top of the vacuum chamber, and is coupled and fixed by a predetermined coupler to the vacuum chamber.

12. The apparatus of claim 10, further comprising: a capacitor at the front end of the second straightline part of the coil shape antenna.

13. The apparatus of claim 11, further comprising: a capacitor at the front end of the second straightline part of the coil shape antenna.

14. The apparatus of claim 12, wherein the capacitor is formed by intervening a dielectric substance between the front end of the second straightline part and the concave groove part of the vacuum chamber.

15. The apparatus of claim 13, wherein the capacitor is formed by intervening a dielectric substance between the front end of the second straightline part and the concave groove part of the vacuum chamber.

16. The apparatus of claim 14, wherein the antenna unit has a single structure in which a single coil shape antenna extends from the circumferential surface of the plate shape antenna.

17. The apparatus of claim 15, wherein the antenna unit has a single structure in which a single coil shape antenna extends from the circumferential surface of the plate shape antenna.

18. The apparatus of claim 14, wherein the antenna unit has a complex structure in which a plurality of coil shape antennas extend from the circumferential surface of the plate shape antenna.

19. The apparatus of claim 15, wherein the antenna unit has a complex structure in which a plurality of coil shape antennas extend from the circumferential surface of the plate shape antenna.

20. The apparatus of claim 1, wherein the antenna unit comprises:
a concave part concaved downward so that a center can be on the same line as the through-hole of the insulating vacuum plate of the vacuum chamber; and
a plurality of gas jet ports provided at a surface of the concave part.

21. The apparatus of claim 20, wherein the antenna unit further comprises a gas distribution plate between the concave part and the antenna cover.

22. The apparatus of claim 6, wherein the plate shape antenna of the antenna unit is of a rectangular plate shape, and
wherein the coil shape antenna is of a multi-bent straightline shape in which it vertically extends from the circumferential surface of the plate shape antenna, extends from an end of a vertical extension in parallel with the rectangular plate shape, and vertically extends outward from an end of a parallel extension.

23. The apparatus of claim 7, wherein the plate shape antenna of the antenna unit is of a rectangular plate shape, and
wherein the coil shape antenna is of a multi-bent straightline shape in which it vertically extends from the circumferential surface of the plate shape antenna, extends from an end of a vertical extension in parallel with the rectangular plate shape, and vertically extends outward from an end of a parallel extension.

24. The apparatus of claim 5, wherein a ratio of Capacitively Coupled Plasma (CCP) component to Inductively Coupled Plasma (ICP) component is controllable by varying an impedance (Z_{ch}) of the vacuum chamber and an impedance (Z_{coil}) of the coil shape antenna.

25. The apparatus of claim 24, wherein the impedance (Z_{ch}) is expressed by Equation:
Z_{ch}=1/ωC_{ch}
where,
Z_{ch}: impedance of vacuum chamber,
C_{ch}: capacitance of vacuum chamber, and
ω: frequency, and
wherein a capacitance (C_{ch}) of the vacuum chamber is expressed by Equation:
C_{ch}=∈(A/d_{gap})
where,
∈: dielectric constant within vacuum chamber,
A: area of plate shape antenna, and
d_{gap}: distance of gap between plate shape antenna and ESC.

26. The apparatus of claim 25, wherein the capacitance (C_{ch}) of the vacuum chamber increases by decreasing the distance (d_{gap}), and a CCP component ratio increases by decreasing the impedance (Z_{ch}).

27. The apparatus of claim 24, wherein the impedance (Z_{coil}) of the coil shape antenna is expressed by Equation:
Z_{coil}=R+jωL+1/jωC
where,
j: imaginary unit (j²=−1),
ω: frequency,
L: inductance, and
C: capacitance, and
wherein the capacitance (C) is expressed by Equation:
C=∈(S/d)
where,
∈: dielectric constant of dielectric substance,
S: area of dielectric substance, and
d: thickness of dielectric substance.

28. The apparatus of claim 1, wherein the vacuum chamber comprises:
upper and lower wall bodies forming a frame of the vacuum chamber and separated in a predetermined position; and
a gap block airtightly interposed between the upper and lower wall bodies,
whereby a capacitance is controlled between an ESC and an antenna unit.

29. The apparatus of claim 1, wherein the vacuum chamber has a short vertical length by a narrow gap to have a high capacitance between an ESC and an antenna unit.

30. The apparatus of claim 1, wherein the vacuum chamber has a long vertical length by a wide gap to have a low capacitance between an ESC and an antenna unit.

31. A plasma generating apparatus comprising:
a vacuum chamber having a hollow interior, covered at an opened top with an insulating vacuum plate, and having a gas injection port thereunder;
an ElectroStatic Chuck (ESC) disposed at an internal center of the vacuum chamber, receiving an external bias RF, and placing a substrate thereon; and
an antenna unit disposed over the insulating vacuum plate to be spaced a predetermined distance apart from the insulating vacuum plate and receiving an external source RF.

32. The apparatus of claim 31, wherein the ESC elevates and descends by a predetermined elevating unit, while controlling a capacitance with the antenna unit.

33. The apparatus of claim 32, wherein the elevating unit is a bellows tube extending from a bottom of the ESC to a bottom of the vacuum chamber.

34. The apparatus of claim 31, wherein the bias RF is separately comprised of a bias low frequency RF and a bias high frequency RF.

35. The apparatus of claim 31, wherein the antenna unit has a coupling structure with a plate shape antenna and a coil shape antenna, and
wherein the plate shape antenna generates plasma by capacitive coupling of inducing an electric field with the ESC, and the coil shape antenna generates plasma by inductive coupling of applying a magnetic field and inducing an inductive electric field within the vacuum chamber.

36. The apparatus of claim 31, further comprising: a gas distribution plate provided at a bottom of the insulating vacuum plate and enabling a uniform downward distribution of a gas injected through the gas injection port.
